(19) United States
(12) Patent Application Publication
(10) Pub. No.: US 2024/0113201 A1
(43) Pub. Date: Apr. 4, 2024

(54) MULTI-GATE DEVICE INNER SPACER AND METHODS THEREOF

(71) Applicant: Taiwan Semiconductor Manufacturing Company, Ltd., Hsinchu (TW)

(72) Inventors: Chih-Ching WANG, Kinmen County (TW); Wei-Yang LEE, Taipei City (TW); Bo-Yu LAI, Taipei City (TW); Chung-I YANG, Hsinchu City (TW); Sung-En LIN, Hsinchu County (TW)

(21) Appl. No.: 18/159,625

(22) Filed: Jan. 25, 2023

Related U.S. Application Data
(60) Provisional application No. 63/377,685, filed on Sep. 29, 2022.

(51) Int. Cl. H01L 29/66; H01L 29/06; H01L 29/423; H01L 29/775

(52) U.S. Cl. CPC H01L 29/66553; H01L 29/0673; H01L 29/42392; H01L 29/66439; H01L 29/66545; H01L 29/775

(57) ABSTRACT

Methods and structures for modulating an inner spacer profile include providing a fin having an epitaxial layer stack including a plurality of semiconductor channel layers interposed by a plurality of dummy layers. In some embodiments, the method further includes removing the plurality of dummy layers to form a first gap between adjacent semiconductor channel layers of the plurality of semiconductor channel layers. Thereafter, in some examples, the method includes conformally depositing a dielectric layer to substantially fill the first gap between the adjacent semiconductor channel layers. In some cases, the method further includes etching exposed lateral surfaces of the dielectric layer to form an etched-back dielectric layer that defines substantially V-shaped recesses. In some embodiments, the method further includes forming a substantially V-shaped inner spacer within the substantially V-shaped recesses.

### CROSS-REFERENCE TO RELATED APPLICATIONS

This application claims priority to U.S. Prov. App. Ser. No. 63/377,685, filed Sep. 29, 2022, the entire disclosure of which is incorporated herein by reference.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). One such multi-gate device that has been introduced is the fin field-effect transistor (FinFET). The FinFET gets its name from the fin-like structure which extends from a substrate on which it is formed, and which is used to form the FET channel. Another multi-gate device, introduced in part to address performance challenges associated with FinFETs, is the gate-all-around (GAA) transistor. GAA transistors get their name from the gate structure which extends completely around the channel, providing better electrostatic control than FinFETs. FinFETs and GAA transistors are compatible with conventional complementary metal-oxide-semiconductor (CMOS) processes and their three-dimensional structure allows them to be aggressively scaled while maintaining gate control and mitigating SCEs.

In general, GAA transistors may be implemented, for example, in cases where FinFETs can no longer meet performance requirements. However, fabrication of GAA transistors has introduced new challenges to the semiconductor manufacturing process and has led to associated device reliability concerns. Thus, existing techniques have not proved entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 provides a simplified top-down layout view of a multi-gate device, in accordance with some embodiments;

FIG. 2 is a flow chart of a method of fabricating a semiconductor device 300 according to one or more aspects of the present disclosure;

FIGS. 3, 4, 5, 6, 7, 9, 10, and 11 provide cross-sectional views of an embodiment of the semiconductor device 300 along a plane substantially parallel to a plane defined by section AA′ of FIG. 1, in accordance with some embodiments;

FIG. 5A provides an enlarged view of a portion of the semiconductor device 300 of FIG. 5, in accordance with some embodiments;

FIG. 6A provides an enlarged view of a portion of the semiconductor device 300 of FIG. 6, in accordance with some embodiments;

FIG. 8A provides an enlarged view of a portion of the semiconductor device 300 of FIG. 8, in accordance with some embodiments; and

FIGS. 12A and 12B provide enlarged views of different embodiments of a portion of the semiconductor device 300 of FIG. 11, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Additionally, in the discussion that follows, dimensions (e.g., such as thickness, width, length, etc.) for a given layer or other feature may at times be described using terms such as “substantially equal”, “equal”, or “about”, where such terms are understood to mean within +/−10% of the recited value or between compared values. For instance, if dimension A is described as being “substantially equal” to dimension B, it will be understood that dimension A is within +/−10% of dimension B. As another example, if a layer is described as having a thickness of about 100 nm, it will be understood that the thickness of the layer may in a range between 90-110 nm.

It is also noted that the present disclosure presents embodiments in the form of multi-gate transistors. Multi-gate transistors include those transistors whose gate structures are formed on at least two-sides of a channel region. These multi-gate devices may include a P-type transistor or an N-type transistor. Specific examples may be presented and referred to herein as FinFETs, on account of their fin-like structure. Also presented herein are embodiments of a type of multi-gate transistor referred to as a gate-all-around (GAA) transistor. A GAA transistor includes any device that has its gate structure, or portion thereof, formed on 4-sides of a channel region (e.g., surrounding a portion of a channel region). Devices presented herein also include embodiments that have channel regions disposed in semiconductor channel layers. In various embodiments, the semiconductor channel layers may include nanosheet channel(s), nanowire channel(s), bar-shaped channel(s), and/or other suitable channel configurations. Presented herein are embodiments of devices that may have one or more channel regions (e.g., semiconductor channel layers) associated with a single, contiguous gate structure. However, one of ordinary skill would recognize that the teaching can apply to a single channel (e.g., single semiconductor channel layer) or any number of channels. One of ordinary skill may recognize other examples of semiconductor devices that may benefit from aspects of the present disclosure.

For GAA transistors, inner spacers are formed between lateral ends of adjacent semiconductor channel layers, and between a source/drain feature and a gate structure formed in a channel region between adjacent semiconductor channel layers. In general, a sidewall profile of the inner spacers is critical for both device performance/yield and may impact drive current, short-channel effects (SCEs), and parasitic (fringing) capacitance. In highly scaled semiconductor devices, the available space within which to form inner spacers is very limited. In some cases, increasing a size of the inner spacer may result in a reduced metal gate critical dimension (CD), which can lead to severe degradation of SCEs. Thus, to maintain a sufficient metal gate CD, the size of the inner spacer and/or the space to an adjacent epitaxial layer (e.g., source/drain epitaxial layer) remains small. Moreover, the metal gate CD may remain substantially uniform across top, middle, and bottom portions of the gate structure formed in the channel region between adjacent semiconductor channel layers. As a result, and in at least some existing implementations, GAA transistors may exhibit worse fringing capacitance and increased process risk such as potential metal gate to source/drain shorting via an inner spacer seam, damage to the source/drain epitaxial layer, or other issues. Thus, existing techniques have not proved entirely satisfactory in all respects.

Embodiments of the present disclosure offer advantages over the existing art, though it is understood that other embodiments may offer different advantages, not all advantages are necessarily discussed herein, and no particular advantage is required for all embodiments. For example, embodiments discussed herein include methods and structures for modulating an inner spacer profile, and thus an associated metal gate profile, of a multi-gate device (e.g., such as a GAA transistor) to address various existing challenges, as discussed above. In some examples, a method of modulating the inner spacer profile includes initially removing SiGe layers that interpose adjacent semiconductor channel layers (e.g., such as by a wet etching process) and re-depositing an oxide or nitride (e.g., such as SiN) layer to conformally fill the cavity formed by removal of the SiGe layers. Thereafter, a recessing process is performed to recess the deposited oxide or nitride layer to form a substantially V-shaped inner spacer recess between lateral ends of adjacent semiconductor channel layers. In some embodiments, the recessing process includes a wet etch using phosphoric acid (H₃PO₄). Afterwards, an inner spacer material is deposited and etched-back (e.g., using a dry etching process) to complete formation of the inner spacer. In particular, the inner spacer material fills the substantially V-shaped inner spacer recess such that the final inner spacer includes a substantially V-shaped inner spacer. In some embodiments, a width of a middle portion of the V-shaped inner spacer is greater than widths of top/bottom portions of the V-shaped inner spacer by about 1-5 nm. After formation of the V-shaped inner spacer, epitaxial source/drain features are formed, and the remaining oxide or nitride layer is removed to form gaps between adjacent semiconductor channel layers within which a metal gate structure is subsequently formed. A sidewall profile of lateral ends of the metal gate structure formed in the gaps between the adjacent semiconductor channel layers interfaces the corresponding V-shaped inner spacer. In particular, and as a result of the V-shaped inner spacer, widths of top/bottom portions of the metal gate structure formed within the gaps between the adjacent semiconductor channel layers are greater than a width of a middle portion of the metal gate structure by about 1-5 nm. As used herein, the term “V-shaped” may generally refer to the shape of the letter ‘V’ of the modern English alphabet, having one end that tapers to a point. To be sure, in some cases, the term V-shaped may also refer to a shape that tapers to a curved end or a square/rectangular end, rather than to a point.

The V-shaped inner spacer process disclosed herein, which simultaneously provides a larger metal gate CD at top/bottom portions of the metal gate structure abutting adjacent semiconductor channel layers, serves to reduce fringing capacitance, while also maintaining gate control of the channel, and providing good SCE control. Further, removal of the SiGe layers in accordance with the methods described herein ensures that there is no SiGe source for potential SiGe condensation or donor-type dopant (Nd) (e.g., such as phosphorous) co-diffusion. The embodiments disclosed herein also provide for reduced process risk including avoiding potential metal gate to source/drain shorting via an inner spacer seam, avoiding damage to the source/drain epitaxial layer, and/or avoiding other issues associated with at least some existing implementations. In addition, the V-shaped inner spacer process disclosed herein is compatible with existing GAA process integration flows, and provides for device structures that are optimized for both DC and AC performance. Other embodiments and advantages will be evident to those skilled in the art upon reading the present disclosure.

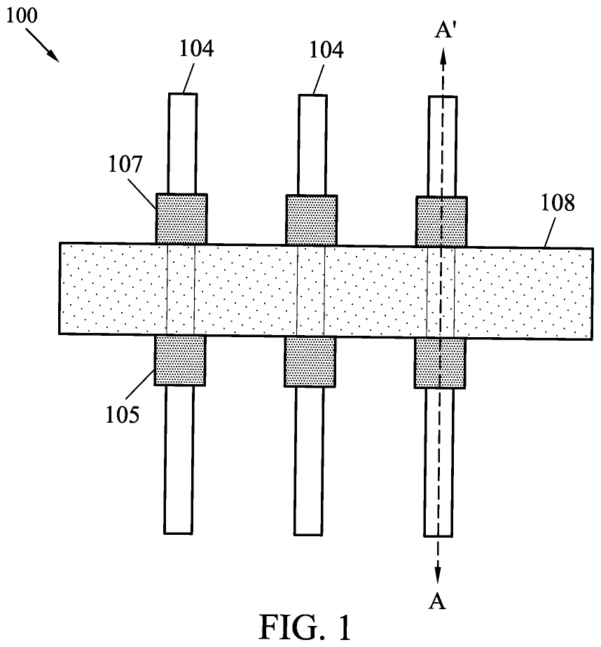

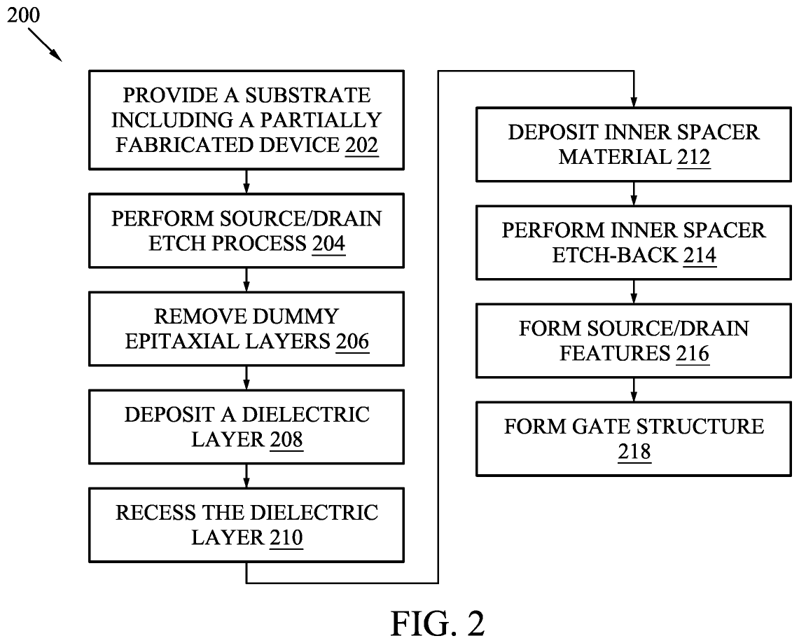

For purposes of the discussion that follows, FIG. 1 provides a simplified top-down layout view of a multi-gate device 100. In various embodiments, the multi-gate device 100 may include a FinFET device, a GAA transistor, or other type of multi-gate device. The multi-gate device 100 may include a plurality of fin elements 104 extending from a substrate, a gate structure 108 disposed over and around the fin elements 104, and source/drain regions 105, 107, where the source/drain regions 105, 107 are formed in, on, and/or surrounding the fins 104. A channel region of the multi-gate device 100, which may include a plurality of semiconductor channel layers (e.g., when the multi-gate device 100 includes a GAA transistor), is disposed within the fins 104, underlying the gate structure 108, along a plane substantially parallel to a plane defined by section AA′ of FIG. 1. In some embodiments, sidewall spacers may also be formed on sidewalls of the gate structure 108. Various other features of the multi-gate device 100 are discussed in more detail below with reference to the method of FIG. 2.

Referring to FIG. 2, illustrated therein is a method 200 of semiconductor fabrication including fabrication of a semiconductor device 300 (e.g., which includes a multi-gate device) having a substantially V-shaped inner spacer, in accordance with various embodiments. The method 200 is discussed below with reference to fabrication of GAA transistors. However, it will be understood that aspects of the method 200 may be equally applied to other types of multi-gate devices, or to other types of devices implemented by the multi-gate devices, without departing from the scope of the present disclosure. In some embodiments, the method 200 may be used to fabricate the multi-gate device 100, described above with reference to FIG. 1. Thus, one or more aspects discussed above with reference to the multi-gate device 100 may also apply to the method 200. It is understood that the method 200 includes steps having features of a complementary metal-oxide-semiconductor (CMOS) technology process flow and thus, are only described briefly herein. Also, additional steps may be performed before, after, and/or during the method 200.

It is further noted that, in some embodiments, the semiconductor device 300 may include various other devices and features, such as other types of devices such as additional transistors, bipolar junction transistors, resistors, capacitors, inductors, diodes, fuses and/or other logic circuits, etc., but is simplified for a better understanding of the inventive concepts of the present disclosure. In some embodiments, the semiconductor device 300 may include a plurality of semiconductor devices (e.g., transistors) which may be interconnected. Moreover, it is noted that the process steps of method 200, including any descriptions given with reference to the figures are merely exemplary and are not intended to be limiting beyond what is specifically recited in the claims that follow.

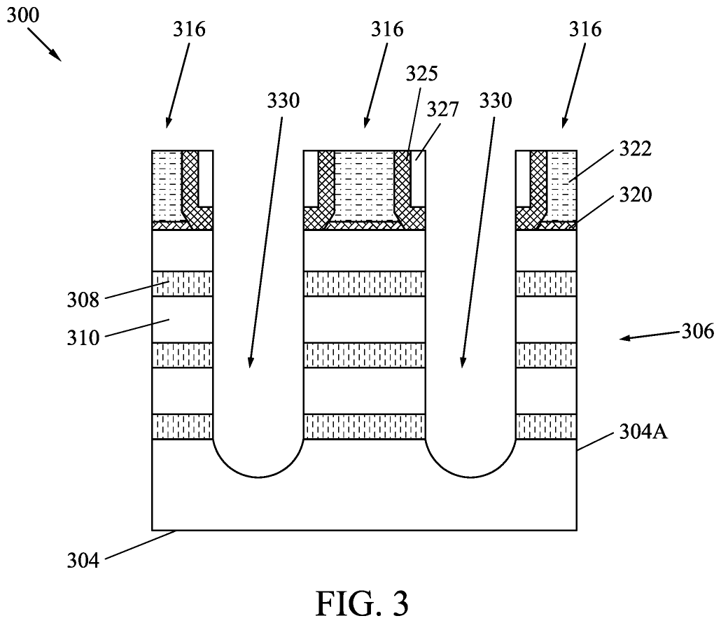

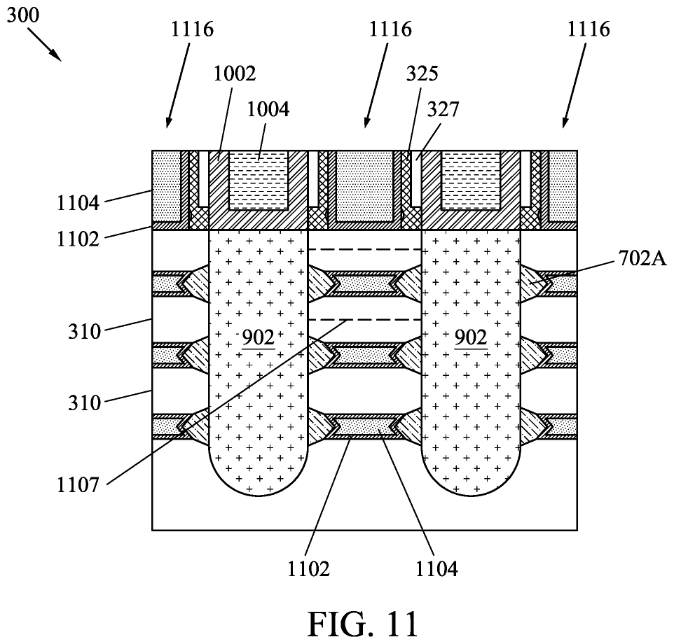

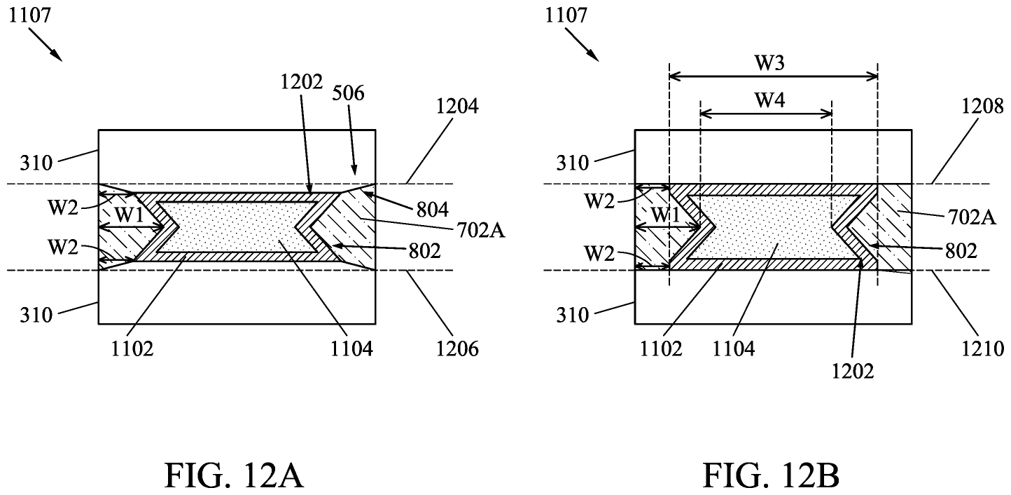

The method 200 begins at block 202 where a substrate including a partially fabricated device is provided. Referring to the example of FIG. 3, in an embodiment of block 202, a partially fabricated device 300 is provided. FIGS. 3-11 provide cross-sectional views of an embodiment of the semiconductor device 300 along a plane substantially parallel to a plane defined by section AA′ of FIG. 1 (e.g., along the direction of a fin 306). FIG. 12A provides an enlarged view of a portion of the semiconductor device 300 of FIG. 11, and FIG. 12B provides an enlarged view of another embodiment of the portion of the semiconductor device 300 of FIG. 11, illustrating examples of inner spacer sidewall profiles and associated metal gate sidewall profiles.

The device 300 may be formed on a substrate 304. In some embodiments, the substrate 304 may be a semiconductor substrate such as a silicon substrate. The substrate 304 may include various layers, including conductive or insulating layers formed on a semiconductor substrate. The substrate 304 may include various doping configurations depending on design requirements as is known in the art. The substrate 304 may also include other semiconductors such as germanium, silicon carbide (SiC), silicon germanium (SiGe), or diamond. Alternatively, the substrate 304 may include a compound semiconductor and/or an alloy semiconductor. Further, the substrate 304 may optionally include an epitaxial layer (epi-layer), may be strained for performance enhancement, may include a silicon-on-insulator (SOI) structure, and/or have other suitable enhancement features.

As shown in FIG. 3, the device 300 includes a fin 306 having a substrate portion 304A (formed from the substrate 304), epitaxial layers 308 of a first composition and epitaxial layers 310 of a second composition that interpose the layers 308 of the first composition. In some cases, shallow trench isolation (STI) features may be formed to isolate the fin 306 from neighboring fins. For purposes of this discussion, the epitaxial layers 308 of the first composition include dummy layers, and the epitaxial layers 310 of the second composition include semiconductor channel layers. In an embodiment, the epitaxial layers 308 of the first composition include SiGe and the epitaxial layers of the second composition 310 include silicon (Si). It is also noted that while the layers 308, 310 are shown as having a particular stacking sequence within the fin 306, where the layer 310 is the topmost layer of the stack of layers 308, 310, other configurations are possible. For example, in some cases, the layer 308 may alternatively be the topmost layer of the stack of layers 308, 310. Stated another way, the order of growth for the layers 308, 310, and thus their stacking sequence, may be switched or otherwise be different than what is shown in the figures, while remaining within the scope of the present disclosure.

In various embodiments, the epitaxial layers 310 (e.g., including the second composition), or portions thereof, may form a channel region of a GAA transistor of the device 300. For example, the layers 310 may be referred to as semiconductor channel layers that are used to form a channel region of a GAA transistor. In various embodiments, the semiconductor channel layers (e.g., the layers 310 or portions thereof) may include nanosheet channel(s), nanowire channel(s), bar-shaped channel(s), and/or other suitable channel configurations. The semiconductor channel layers may also be used to form portions of the source/drain features of the GAA transistor, in some embodiments.

It is noted that while the fin 306 is illustrated as including three (3) layers of the epitaxial layer 308 and three (3) layers of the epitaxial layer 310, this is for illustrative purposes only and not intended to be limiting beyond what is specifically recited in the claims. It can be appreciated that any number of epitaxial layers can be formed, where for example, the number of epitaxial layers depends on the desired number of semiconductor channel layers for the GAA transistor. In some embodiments, the number of epitaxial layers 310, and thus the number of semiconductor channel layers, is between 3 and 10.

In some embodiments, the epitaxial layers 308 (the dummy layers) each have a thickness in a range of about 4-8 nanometers (nm). In some cases, the epitaxial layers 310 (the semiconductor channel layers) each have a thickness in a range of about 4-8 nm. As noted above, the epitaxial layers 310 may serve as channel region(s) for a subsequently formed multi-gate device (e.g., a GAA transistor) and its thickness may be chosen based at least in part on device performance considerations. The epitaxial layers 308 may serve to define a gap distance between adjacent channel region(s) for the subsequently formed multi-gate device and its thickness may also be chosen based at least in part on device performance considerations.

The device 300 further includes gate stacks 316 formed over the fin 306. In an embodiment, the gate stacks 316 are dummy (sacrificial) gate stacks that are subsequently removed and replaced by a final gate stack at a subsequent processing stage of the device 300. For example, the gate stacks 316 may be replaced at a later processing stage by a high-K dielectric layer (HK) and metal gate electrode (MG). While the present discussion is directed to a replacement gate (gate-last) process whereby a dummy gate structure is formed and subsequently replaced, other configurations may be possible (e.g., such as a gate-first process). The portion of the fin 306 underlying the gate stacks 316 may be referred to as the channel region of the device 300. The gate stacks 316 may also define source/drain regions of the fin 306, for example, the regions of the fin 306 adjacent to and on opposing sides of the channel region.

In some embodiments, the gate stacks 316 include a dielectric layer 320 and an electrode layer 322 over the dielectric layer 320. In some embodiments, the dielectric layer 320 includes silicon oxide. Alternatively, or additionally, the dielectric layer 320 may include silicon nitride, a high-K dielectric material or other suitable material. In some embodiments, the electrode layer 322 may include polycrystalline silicon (polysilicon). In some embodiments, and after formation of the gate stacks 316, one or more spacer layers 325, 327 may be formed on sidewalls of the gate stacks 316. In some cases, the one or more spacer layers 325, 327 may include a dielectric material such as silicon oxide, silicon nitride, silicon carbide, silicon oxynitride, SiCN, silicon oxycarbide, SiOCN, a low-K material (e.g., with a dielectric constant ‘k’<7), and/or combinations thereof. In some embodiments, the one or more spacer layers 325, 327 include multiple layers, such as main spacer layers, liner layers, and the like.

The method 200 then proceeds to block 204 where a source/drain etch process is performed. Still with reference to FIG. 3, in an embodiment of block 204, a source/drain etch process is performed to the device 300. In some embodiments, the source/drain etch process is performed to remove the exposed epitaxial layers 308, 310 in source/drain regions of the device 300 to form trenches 330 which expose underlying portions of the substrate 304. The source/drain etch process also serves to expose lateral surfaces of the epitaxial layers 308, 310, as shown in FIG. 3. In some embodiments, the source/drain etch process may also remove portions of the one or more spacer layers 325, 327. In some embodiments, the source/drain etch process may include a dry etching process, a wet etching process, and/or a combination thereof.

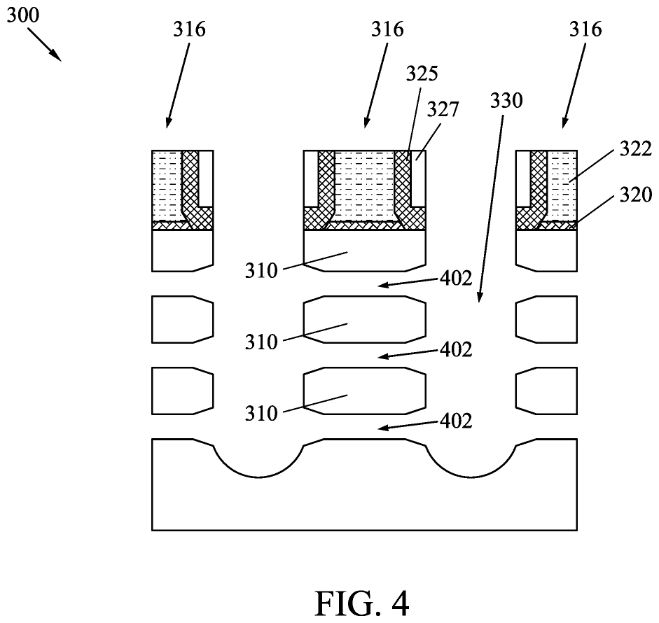

The method proceeds to block 206 where dummy epitaxial layers are removed. Referring to the example of FIGS. 3 and 4, in an embodiment of block 206, the dummy epitaxial layers (the epitaxial layers 308) are selectively removed (e.g., using a selective etching process), while the semiconductor channel layers (the epitaxial layers 310) remain unetched. To be sure, in various examples, the selective removal of the dummy epitaxial layers completely removes the epitaxial layers 308. The selective etching process may be performed through the trenches 330 provided by the source/drain etch process (block 204). In some embodiments, the selective etching process may include a selective wet etching process. In some cases, the selective wet etching includes ammonia (NH₃) and/or ozone (O₃). As merely one example, the selective wet etching process includes tetra-methyl ammonium hydroxide (TMAH). In some embodiments, the selective etching process may include a dry, plasma-free etching process performed using a CERTAS® Gas Chemical Etch System, available from Tokyo Electron Limited, Tokyo, Japan. In some examples, the selective etching process may include etching using a standard clean 1 (SC-1) solution, a solution of ammonium hydroxide (NH₄OH), hydrogen peroxide (H₂O₂) and water (H₂O), hydrofluoric acid (HF), buffered HF, and/or a fluorine (F₂)-based etch. In some examples, the F₂-based etch may include an F₂ remote plasma etch. It is noted that as a result of the selective removal of the dummy epitaxial layers (the epitaxial layers 308), gaps (or cavities) 402 are formed between the adjacent semiconductor channel layers (the epitaxial layers 310).

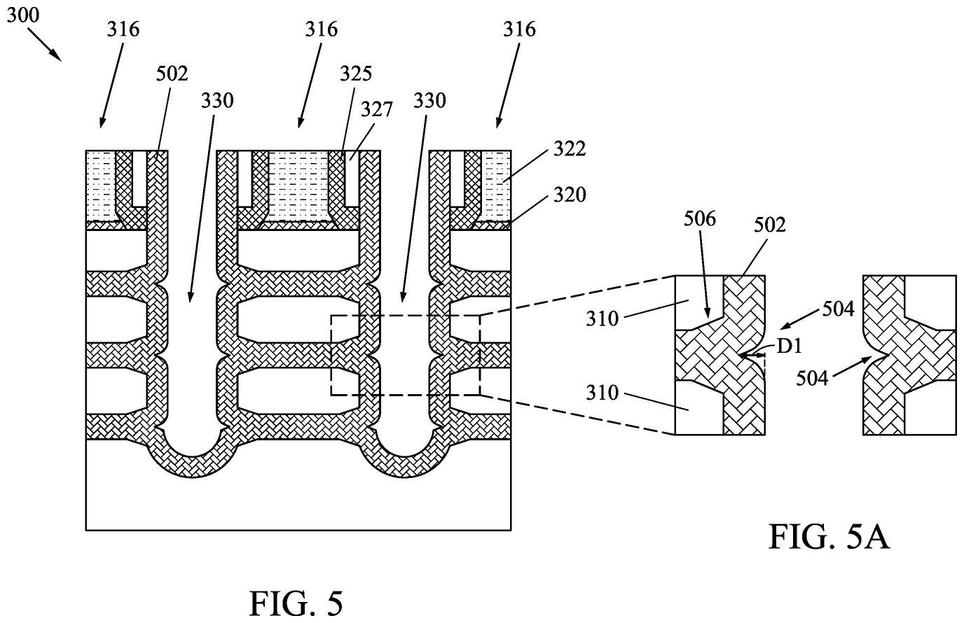

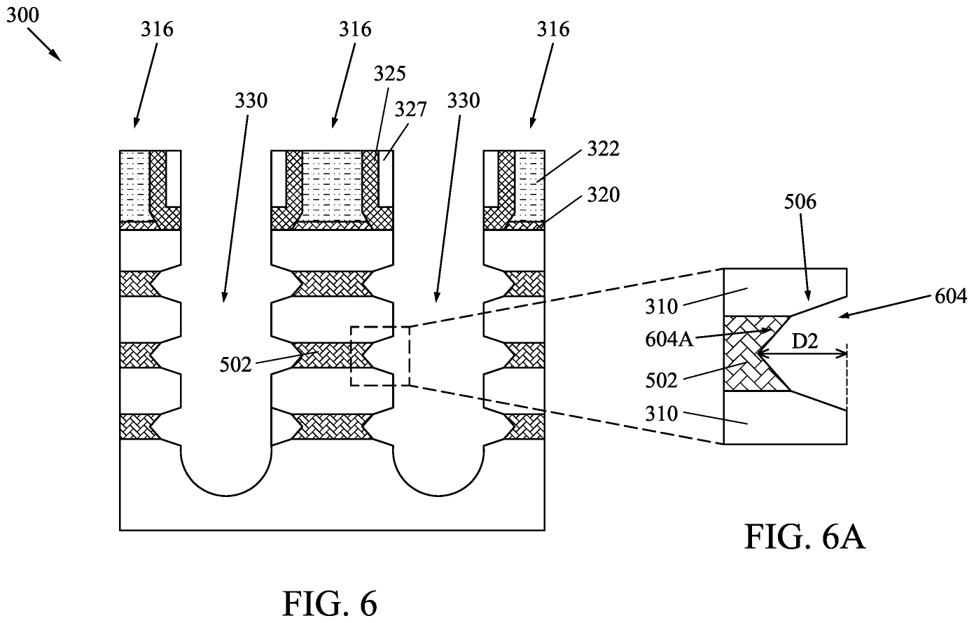

In some cases, and as a result of the removal of the dummy epitaxial layers (block 206), ends of the epitaxial layers 310 in LDD regions of the device 300 (e.g., beneath the one or more spacer layers 325, 327 on opposing ends of the channel region) may be partially etched such that the epitaxial layers 310 may be slightly thinner in the LDD region as compared to the channel region (e.g., directly beneath the gate stacks 316). In some cases, this may result in slanted surfaces 506 of the epitaxial layers 310 in the LDD regions of the device 300, as more clearly illustrated in FIGS. 5A and 6A. By way of example, the consumption from each of the top and bottom surfaces of the epitaxial layers 310 in the LDD region, as a result of the removal of the dummy epitaxial layers, may be in a range of about 0.5-1 nm, for a total consumption from both top and bottom surfaces of the epitaxial layers 310 of about 1-2 nm. To be sure, in some embodiments, ends of the epitaxial layers 310 in the LDD region may not be etched during the removal of the dummy epitaxial layers, and the ends of the epitaxial layers 310 in the LDD regions of the device 300 may thus remain substantially rectangular shaped.

After removal of the dummy epitaxial layers (block 206), the method 200 then proceeds to block 208 where a dielectric layer is deposited. Referring to FIGS. 4 and 5/5A, in an embodiment of block 208, a dielectric layer 502 is conformally deposited over the device 300 and within the trenches 330. The dielectric layer 502 is also conformally deposited within the gaps (or cavities) 402 that were previously formed between the adjacent semiconductor channel layers (the epitaxial layers 310). In particular, the dielectric layer 502 is deposited such that it completely fills the gaps (or cavities) 402. In some embodiments, the dielectric layer 502 may include an oxide layer (e.g., such as SiO₂) or a nitride layer (e.g., such as SiN). In some examples, the dielectric layer 502 may include another dielectric material such as silicon carbide, silicon oxynitride, SiCN, silicon oxycarbide, SiOCN, a low-K material (e.g., with a dielectric constant ‘k’<7), and/or combinations thereof. In some cases, the dielectric layer 502 may be conformally deposited using processes such as a CVD process, a subatmospheric CVD (SACVD) process, a flowable CVD process, an ALD process, a PVD process, or other suitable process. As shown in FIG. 5A, and as a result of the conformal deposition of the dielectric layer 502, the dielectric layer 502 may define substantially V-shaped recesses 504. In some embodiments, the V-shaped recesses 504 may have a depth ‘D1’, as measured from a plane defined by an exposed surface of the dielectric layer 502 disposed on a lateral surface of an adjacent epitaxial layer 310 to an apex of the V-shaped recesses 504.

The method 200 then proceeds to block 210 where the previously deposited dielectric layer is recessed. Referring to FIGS. 5/5A and FIGS. 6/6A, in an embodiment of block 210, a recessing process is performed to the device 300. In various examples, the recessing process etches the dielectric layer 502 from over the device 300 and from along sidewalls of the trenches 330, while the dielectric layer 502 remains at least partially disposed between the adjacent semiconductor channel layers (the epitaxial layers 310). Stated another way, the recessing process of block 210 at least partially etches the dielectric layer 502 from between lateral ends of the adjacent semiconductor channel layers (the epitaxial layers 310) to form substantially V-shaped recesses 604 having V-shaped sidewall profiles 604A along a lateral surface of the dielectric layer 502 (e.g., facing the trench 330). In various embodiments, the V-shaped recesses 604 serve to define subsequently formed V-shaped inner spacers, as discussed below. In some embodiments, the V-shaped recesses 604 may have a depth ‘D2’, as measured from a plane defined by an exposed lateral surface of an adjacent epitaxial layer 310 to an apex of the V-shaped recesses 604. In some embodiments, the V-shaped recesses 604 formed as a result of the recessing process (block 210) may be larger than the V-shaped recesses 504 formed as a result of the conformal deposition of the dielectric layer 502 (block 208). Thus, in some cases, the depth ‘D2’ of the V-shaped recesses 604 may be greater than the depth ‘D1’ of the V-shaped recesses 504. By way of example, the recessing process (block 210) may be performed using a wet etch process. In some embodiments, the wet etch process may include a phosphoric acid (H₃PO₄) chemical etch of the dielectric layer 502. In some alternative examples, cycles of a high temperature sulfuric peroxide mixture (HTSPM) and dilute hydrofluoric acid (dHF), ozone (O₃) and dHF, or a combination thereof, may be used to perform the recessing process.

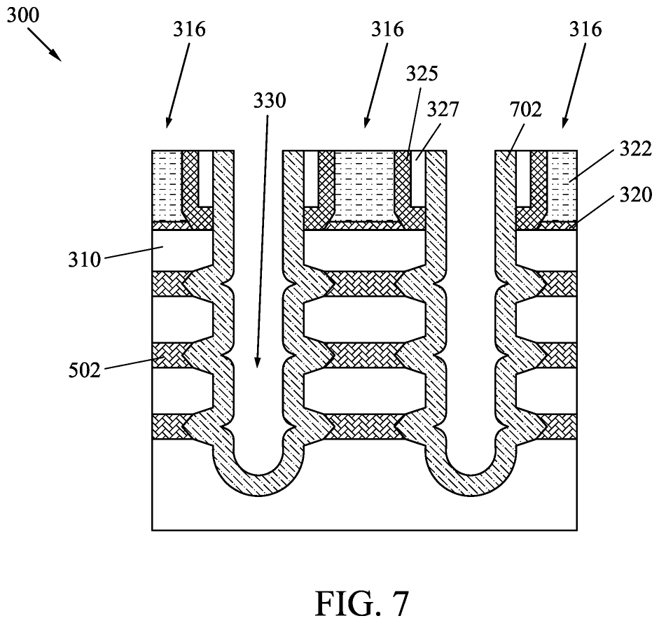

The method 200 then proceeds to block 212 where an inner spacer material is deposited. Referring to FIG. 6 and FIG. 7, in an embodiment of block 212, an inner spacer material 702 is conformally deposited over the device 300, within the trenches 330 and within the V-shaped recesses 604 (e.g., formed by recessing the dielectric layer 502 at block 210). It is noted that the inner spacer material 702 substantially fills the V-shaped recesses 604, such that subsequently formed inner spacers are also V-shaped, as discussed below. In some embodiments, the inner spacer material 702 may include amorphous silicon. In some examples, the inner spacer material 702 may include a dielectric material such as silicon oxide, silicon nitride, silicon carbide, silicon oxynitride, SiCN, silicon oxycarbide, SiOCN, a low-K material (e.g., with a dielectric constant ‘k’<7), and/or combinations thereof. By way of example, the inner spacer material 702 may be formed by conformally depositing the inner spacer material 702 over the device 300 using processes such as a CVD process, a SACVD process, a flowable CVD process, an ALD process, a PVD process, or other suitable process.

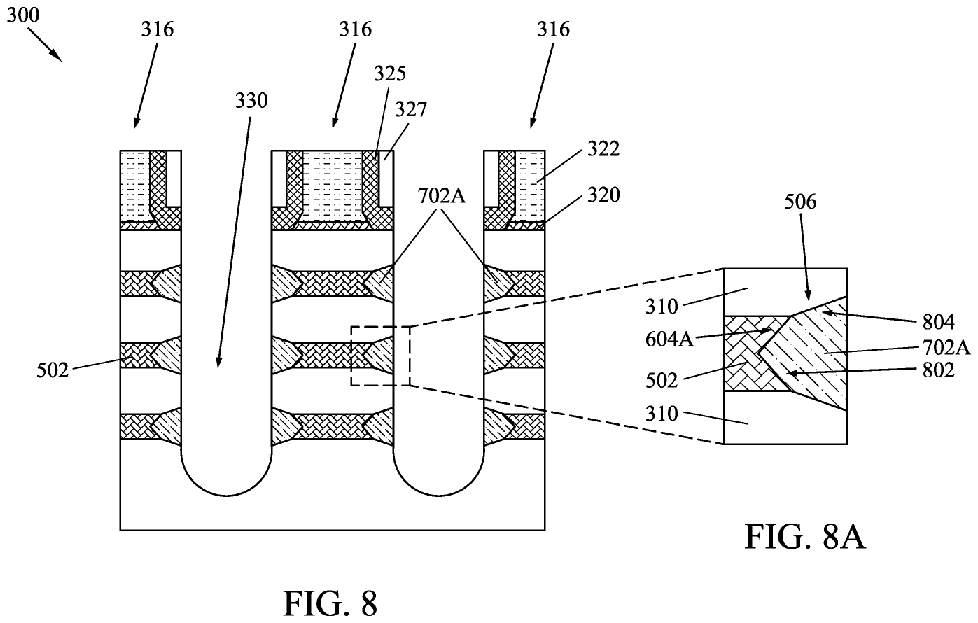

The method 200 then proceeds to block 214 where an inner spacer etch-back process is performed. Referring to FIG. 7 and FIGS. 8/8A, in an embodiment of block 214, an inner spacer etch-back process is performed to etch the inner spacer material 702 from over the device 300 and along sidewalls of the trenches 330, while the inner spacer material remains disposed within the V-shaped recesses 604, thereby providing inner spacers 702A for the device 300. As shown in FIGS. 8 and 8A, the inner spacers 702A are formed in contact with the V-shaped sidewall profiles 604A of the recessed dielectric layer 502 having the V-shaped recesses 604 such that the inner spacers 702A define a complementary V-shaped sidewall profile 802 that interfaces the V-shaped sidewall profiles 604A. In addition, in some embodiments and because the inner spacers 702A are also formed in contact with the slanted surfaces 506 of the epitaxial layers 310, the inner spacers 702A may likewise define a complementary slanted surface 804. The inner spacer etch-back process used to form the inner spacers 702A may include a wet etch process, a dry etch process, or a combination thereof. In some cases, any residual portions of the inner spacer material that remain on top surfaces of the device 300 and/or on sidewalls or bottom surfaces of the trenches 330, for example after the inner spacer etch-back process, may be removed during a subsequent clean process (e.g., prior to epitaxial growth of source/drain features). In various examples, the inner spacers 702A may extend beneath the one or more spacer layers 325, 327 formed on sidewalls of the gate stacks 316 while being disposed adjacent to subsequently formed source/drain features, as described below. In some cases, the inner spacers 702A may extend at least partially beneath the gate stacks 316.

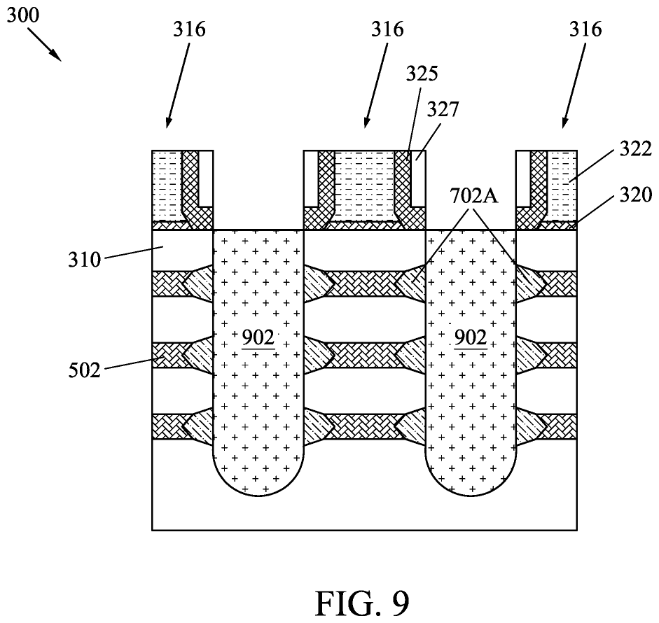

The method 200 then proceeds to block 216 where source/drain features are formed. Referring to FIGS. 8 and 9, in an embodiment of block 216 and after formation of the inner spacers 702A, source/drain features 902 are formed in the source/drain regions adjacent to and on either side of the gate stacks 316 of the device 300. For example, the source/drain features 902 may be formed within the trenches 330 of the device 300, over the exposed portions of the substrate 304 and in contact with the adjacent inner spacers 702A and the semiconductor channel layers (the epitaxial layers 310) of the device 300. In some embodiments, a clean process may be performed immediately prior to formation of the source/drain features 902 to remove any residual portions of inner spacer material, as previously noted. The clean process may include a wet etch, a dry etch, or a combination thereof.

In some embodiments, the source/drain features 902 are formed by epitaxially growing a semiconductor material layer in the source/drain regions. In various embodiments, the semiconductor material layer grown to form the source/drain features 902 may include Ge, Si, GaAs, AlGaAs, SiGe, GaAsP, SiP, or other suitable material. The source/drain features 902 may be formed by one or more epitaxial (epi) processes. In some embodiments, the source/drain features 902 may be in-situ doped during the epi process. For example, in some embodiments, epitaxially grown SiGe source/drain features may be doped with boron. In some cases, epitaxially grown Si epi source/drain features may be doped with carbon to form Si:C source/drain features, phosphorous to form Si:P source/drain features, or both carbon and phosphorous to form SiCP source/drain features. In some embodiments, the source/drain features 902 are not in-situ doped, and instead an implantation process is performed to dope the source/drain features 902.

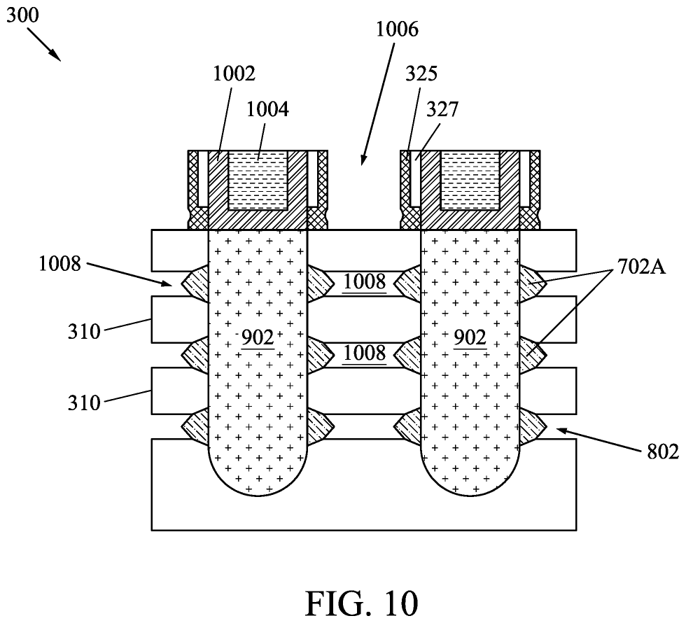

After forming the source/drain features 902, and in some embodiments, a contact etch stop layer (CESL) 1002 may be conformally formed over the device 300, as shown in FIG. 10. In some examples, the CESL 1002 may include a silicon nitride layer, silicon oxide layer, a silicon oxynitride layer, and/or other materials known in the art. In some embodiments, an inter-layer dielectric (ILD) layer 1004 may be formed over the CESL 1002, as also shown in FIG. 10. In various cases, the ILD layer 1004 may include materials such as tetraethylorthosilicate (TEOS) oxide, un-doped silicate glass, or doped silicon oxide such as borophosphosilicate glass (BPSG), fluorosilicate glass (FSG), phosphosilicate glass (PSG), boron doped silicon glass (BSG), and/or other suitable dielectric materials. In some embodiments, after formation of the ILD layer 1004, the device 300 may be subject to a high thermal budget process to anneal the ILD layer 1004. In some embodiments, after formation of the CESL 1002 and the ILD layer 1004, a chemical mechanical polishing (CMP) process may be performed to remove portions of the ILD layer 1002 and the CESL 1004 overlying the gate stacks 316, as well as any hard mask layers that may be present over the gate stacks 316, to planarize a top surface of the device 300 and expose a top surface of the electrode layer 322 of the gate stacks 316.

The method 200 then proceeds to block 218 where gate structures are formed. Referring to the example of FIGS. 9 and 10, in an embodiment of block 218, the electrode layer 322 of the gate stacks 316 (e.g., exposed by the CMP process, as noted above) may initially be removed by suitable etching processes to form trenches 1006 that expose the dielectric layer 320 of the gate stacks 316. Thereafter, in some embodiments, an etching process may be performed to remove the exposed dielectric layer 320 from the trenches 1006. In some examples, the etching processes used to remove the electrode layer 322 and the dielectric layer 320 may include a wet etch, a dry etch, or a combination thereof. It is noted that removal of the electrode layer 322 and the dielectric layer 320 provides for removal of the dummy gates (gate stacks 316), for example, as part of a replacement gate process.

Still referring to the example of FIGS. 9 and 10, in a further embodiment of block 218 and after removal of the electrode layer 322 and the dielectric layer 320, the portions of the dielectric layer 502 that remain disposed between adjacent semiconductor channel layers (the epitaxial layers 310) in the channel region of the device 300 may be selectively removed (e.g., using a selective etching process), while the semiconductor channel layers (the epitaxial layers 310) and the V-shaped inner spacers 702A remain substantially unetched. The selective etching process may be performed through the trenches 1006 provided by the removal of the dummy gate electrode. In some embodiments, the selective etching process may include a selective wet etching process. In some cases, the selective wet etching includes ammonia (NH₃) and/or ozone (O₃). As merely one example, the selective wet etching process includes tetra-methyl ammonium hydroxide (TMAH). In some embodiments, the selective etching process may include a dry, plasma-free etching process performed using a CERTAS® Gas Chemical Etch System, available from Tokyo Electron Limited, Tokyo, Japan. In some examples, the selective etching process may include etching using a standard clean 1 (SC-1) solution, a solution of ammonium hydroxide (NH₄OH), hydrogen peroxide (H₂O₂) and water (H₂O), hydrofluoric acid (HF), buffered HF, and/or a fluorine (F₂)-based etch. In some examples, the F₂-based etch may include an F₂ remote plasma etch.

It is noted that as a result of the selective removal of the remaining portions of the dielectric layer 502, gaps 1008 are formed between the adjacent semiconductor channel layers (the epitaxial layers 310) in the channel region of the device 300. By way of example, the gaps 1008 serve to expose first portions of the epitaxial layers 310 between opposing inner spacers 702A, while second portions of the epitaxial layers 310 remain covered by the inner spacers 702A. It is also noted that formation of the gaps 1008 exposes the V-shaped sidewall profile 802 of the inner spacers 702A on opposing sides of the gaps 1008. As described in more detail below, portions of gate structures (e.g., including a metal gate stack having an interfacial layer, a high-K dielectric layer, and one or more metal electrode layers) will be formed within the gaps 1008 between adjacent semiconductor channel layers (the epitaxial layers 310) and in contact with the V-shaped sidewall profile 802 of the inner spacers 702A. Thus, in some examples, lateral ends of the portions of gate structures that are formed within the gaps 1008, and which are in contact with the V-shaped sidewall profile 802, will have a complementary V-shaped sidewall profile.

Referring to the example of FIGS. 10 and 11, in a further embodiment of block 218, final gate structures 1116 for the device 300 are formed. The gate structures 1116 may include a high-K/metal gate stack, however other compositions are possible. In some embodiments, the gate structures 1116 may form the gate associated with the multi-channels provided by the plurality of exposed semiconductor channel layers (the exposed epitaxial layers 310, previously having gaps 1008 therebetween) in the channel region of the device 300. In some embodiments, the gate structures 1116 include a dielectric layer 1102 formed on exposed surfaces of the epitaxial layers 310 (semiconductor channel layers), including on the exposed first portions of the epitaxial layers 310 within the gaps 1008 and between opposing surfaces of the V-shaped sidewall profile 802 of the inner spacers 702A, as well as on surfaces of the V-shaped sidewall profile 802 of the inner spacers 702A themselves. In some embodiments, the dielectric layer 1102 includes an interfacial layer (IL) and a high-K dielectric layer formed over the IL. In various embodiments, the IL and the high-K dielectric layer collectively define a gate dielectric of the gate structure for the device 300. In some embodiments, the gate dielectric has a total thickness of about 1-5 nm. High-K gate dielectrics, as used and described herein, include dielectric materials having a high dielectric constant, for example, greater than that of thermal silicon oxide (˜3.9).

In some embodiments, the IL may include a dielectric material such as silicon oxide (SiO₂), HfSiO, or silicon oxynitride (SiON). In some examples, the high-K dielectric layer may include hafnium oxide (HfO₂). Alternatively, the high-K dielectric layer may include other high-K dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), combinations thereof, or other suitable material. In various embodiments, the gate dielectric may be formed by thermal oxidation, ALD, physical vapor deposition (PVD), pulsed laser deposition (PLD), CVD, and/or other suitable methods.

Still referring to the examples of FIGS. 10 and 11, a metal gate including a metal layer 1104 is formed over the gate dielectric (e.g., over the IL and the high-K dielectric layer). The metal layer 1104 may include a metal, metal alloy, or metal silicide. Additionally, the formation of the gate dielectric/metal gate stack may include depositions to form various gate materials, one or more liner layers, and one or more CMP processes to remove excessive gate materials and thereby planarize a top surface of the device 300.

In some embodiments, the metal layer 1104 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the metal layer 1104 may include Ti, Ag, Al, TiAlN, TaC, TaCN, TaSiN, Mn, Zr, TiN, TaN, Ru, Mo, Al, WN, Cu, W, Re, Ir, Co, Ni, other suitable metal materials or a combination thereof. In various embodiments, the metal layer 1104 may be formed by ALD, PVD, CVD, e-beam evaporation, or other suitable process. Further, the metal layer 1104 may be formed separately for N-type and P-type transistors which may use different metal layers. In addition, the metal layer 1104 may provide an N-type or P-type work function, may serve as a transistor (e.g., GAA transistor) gate electrode, and in at least some embodiments, the metal layer 1104 may include a polysilicon layer. With respect to the devices shown and discussed, the gate structure includes portions that interpose each of the epitaxial layers 310, which each provide semiconductor channel layers for the GAA transistors.

To provide some additional detail regarding the epitaxial layers 310, as well as the sidewall profiles of the inner spacers 702A and the portions of the gate structures 1116 that interpose the semiconductor channel layers (the epitaxial layers 310), reference is made to FIGS. 12A and 12B, which provide enlarged views of different embodiments of a portion 1107 of the semiconductor device 300 of FIG. 11. As shown in FIG. 12A, the epitaxial layers 310 in the LDD regions may have the slanted surfaces 506, as previously described. In addition, the inner spacers 702A include the V-shaped sidewall profile 802, and the lateral ends of the portions of gate structures 1116 that are adjacent to and in contact with the V-shaped sidewall profile 802 have a complementary V-shaped sidewall profile 1202. In some cases, and due to the slanted surfaces 506 of the epitaxial layers 310 in the LDD regions, topmost and bottommost portions of the inner spacers 702A have complementary slanted surfaces 804. As a result, in some embodiments, the topmost portion of the inner spacers 702A on either side of the portion of the gate structure 1116 between adjacent epitaxial layers 310 define a horizontal plane 1204 that is disposed above a topmost surface of the portion of the gate structure 1116 between the adjacent epitaxial layers 310. Similarly, in some embodiments, the bottommost portion of the inner spacers 702A on either side of the portion of the gate structure 1116 between adjacent epitaxial layers 310 define a horizontal plane 1206 that is disposed beneath a bottommost surface of the portion of the gate structure 1116 between the adjacent epitaxial layers 310.

Referring to FIG. 12B, and in an alternative embodiment, the epitaxial layers 310 in the LDD regions do not have the slanted surfaces 506, and the topmost and bottommost portions of the inner spacers 702A in the LDD regions also do not have the slanted surfaces 804, as described above. As a result, in some embodiments, a top surface of the inner spacers 702A on either side of the portion of the gate structure 1116 between adjacent epitaxial layers 310 define a horizontal plane 1208 that is substantially level with (co-planar) a top surface of the portion of the gate structure 1116 between the adjacent epitaxial layers 310. Similarly, in some embodiments, a bottom surface of the inner spacers 702A on either side of the portion of the gate structure 1116 between adjacent epitaxial layers 310 define a horizontal plane 1210 that is substantially level with (co-planar) a bottom surface of the portion of the gate structure 1116 between the adjacent epitaxial layers 310. In this example, the inner spacers 702A still include the V-shaped sidewall profile 802, and the lateral ends of the portions of gate structures 1116 that are adjacent to and in contact with the V-shaped sidewall profile 802 have the complementary V-shaped sidewall profile 1202.

FIGS. 12A and 12B also illustrate that a width W1 of a middle portion of the V-shaped inner spacer 702A is greater than a width W2 of top/bottom portions of the V-shaped inner spacer 702A. In some examples, the width W1 is greater than the width W2 by about 1-5 nm. As a result of the V-shaped inner spacer 702A, and as also shown in FIGS. 12A and 12B, a width W3 of top/bottom portions of the portion of the gate structure 1116 between the adjacent epitaxial layers 310 is greater than a width W4 of a middle portion of the portion of the gate structure 1116 between the adjacent epitaxial layers 310. In some embodiments, the width W3 is greater than the width W4 by about 1-5 nm. In various embodiments, the larger width W4 (as compared to W3) effectively provides a larger metal gate CD at top/bottom portions of the portion of the gate structure 1116 between the adjacent epitaxial layers 310, thereby preserving good gate control of the channel of the device 300 and providing good SCE control. In addition, the larger width W1 (as compared to W2), and the corresponding smaller W4, increases an underlap of the gate structure 1116 with respect to the adjacent epitaxial layers 310, thereby reducing fringing capacitance and mitigating any potential capacitance penalty.

Generally, the semiconductor device 300 may undergo further processing to form various features and regions known in the art. For example, further processing may form various contacts/vias/lines and multilayer interconnect features (e.g., metal layers and interlayer dielectrics) on the substrate 304, configured to connect the various features to form a functional circuit that may include one or more multi-gate devices (e.g., one or more GAA transistors). In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 200, and some process steps described above may be modified, replaced, or eliminated in accordance with various embodiments of the method 200.

With respect to the description provided herein, disclosed are methods and structures for modulating an inner spacer profile, and thus an associated metal gate profile, of a multi-gate device (e.g., such as a GAA transistor) to address various existing challenges, as discussed above. In some examples, a method of modulating the inner spacer profile includes initially removing SiGe layers that interpose adjacent semiconductor channel layers and re-depositing an oxide or nitride layer to conformally fill the cavity formed by removal of the SiGe layers. Thereafter, a recessing process is performed to recess the deposited oxide or nitride layer to form a substantially V-shaped inner spacer recess between lateral ends of adjacent semiconductor channel layers. An inner spacer material is then deposited and etched-back to complete formation of a V-shaped inner spacer. After formation of the V-shaped inner spacer, epitaxial source/drain features are formed, and the remaining oxide or nitride layer is removed to form gaps between adjacent semiconductor channel layers within which a metal gate structure is subsequently formed. A sidewall profile of lateral ends of the metal gate structure formed in the gaps between the adjacent semiconductor channel layers interfaces the V-shaped inner spacer and thus has a complementary V-shaped sidewall profile. In accordance with the embodiments disclosed herein, the V-shaped inner spacer process serves to reduce fringing capacitance, while also maintaining gate control of the channel, and providing good SCE control. Further, removal of the SiGe layers in accordance with the methods described herein ensures that there is no SiGe source for potential SiGe condensation or donor-type dopant (Nd) (e.g., such as phosphorous) co-diffusion. The various embodiments disclosed herein also provide for reduced process risk including avoiding potential metal gate to source/drain shorting via an inner spacer seam, avoiding damage to the source/drain epitaxial layer, and/or avoiding other issues associated with at least some existing implementations. In addition, the V-shaped inner spacer process disclosed herein is compatible with existing GAA process integration flows, and provides for device structures that are optimized for both DC and AC performance.

Thus, one of the embodiments of the present disclosure described a method that includes providing a fin having an epitaxial layer stack including a plurality of semiconductor channel layers interposed by a plurality of dummy layers. In some embodiments, the method further includes removing the plurality of dummy layers to form a first gap between adjacent semiconductor channel layers of the plurality of semiconductor channel layers. Thereafter, in some examples, the method includes conformally depositing a dielectric layer to substantially fill the first gap between the adjacent semiconductor channel layers. In some cases, the method further includes etching exposed lateral surfaces of the dielectric layer to form an etched-back dielectric layer that defines substantially V-shaped recesses. In some embodiments, the method further includes forming a substantially V-shaped inner spacer within the substantially V-shaped recesses.

In another of the embodiments, discussed is a method that includes providing a fin structure including epitaxial layers of a first composition interposed by epitaxial layers of a second composition. In some embodiments, the method further includes forming a dummy gate over the fin structure and a spacer layer on sidewalls of the dummy gate. In some examples, the method further includes replacing the epitaxial layers of the second composition with a conformally deposited dielectric layer. In some embodiments, the method further includes etching back opposing lateral ends of the conformally deposited dielectric layer to form recesses disposed beneath the spacer layer and between adjacent epitaxial layers of the first composition. In some examples, the method further includes forming inner spacers within each of the recesses on the opposing lateral ends of the conformally deposited dielectric layer, where the inner spacers on the opposing lateral ends each include a first V-shaped sidewall profile.

In yet another of the embodiments, discussed is a semiconductor device including a fin extending from a substrate, where the fin includes a plurality of semiconductor channel layers. In some embodiments, the semiconductor device further includes inner spacers disposed between adjacent semiconductor channel layers of the plurality of semiconductor channel layers and on either side of a channel region, where the inner spacers include a first lateral end having a first V-shaped sidewall profile facing the channel region. In some examples, the semiconductor device further includes a source/drain feature disposed within a source/drain region and in contact with a second lateral end of the inner spacers opposite the first lateral end and with end portions of the plurality of semiconductor channel layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a semiconductor device, comprising:
providing a fin including an epitaxial layer stack having a plurality of semiconductor channel layers interposed by a plurality of dummy layers;
removing the plurality of dummy layers to form a first gap between adjacent semiconductor channel layers of the plurality of semiconductor channel layers;
conformally depositing a dielectric layer to substantially fill the first gap between the adjacent semiconductor channel layers;
etching exposed lateral surfaces of the dielectric layer to form an etched-back dielectric layer that defines substantially V-shaped recesses; and
forming a substantially V-shaped inner spacer within the substantially V-shaped recesses.

2. The method of claim 1, further comprising:
prior to removing the plurality of dummy layers, removing portions of the epitaxial layer stack in source/drain regions of the semiconductor device to expose lateral surfaces of the plurality of semiconductor channel layers and the plurality of dummy layers.

3. The method of claim 1, wherein the dielectric layer includes an oxide layer or a nitride layer.

4. The method of claim 1, wherein the etching the exposed lateral surfaces of the dielectric layer includes using a phosphoric acid (H₃PO₄) chemical etch to form the substantially V-shaped recesses.

5. The method of claim 1, wherein the forming the substantially V-shaped inner spacer includes conformally depositing an inner spacer material over the semiconductor device and performing an etch-back process to the inner spacer material, and wherein the inner spacer material remains disposed within the substantially V-shaped recesses after the etch-back process to provide the substantially V-shaped inner spacer.

6. The method of claim 1, wherein the substantially V-shaped recesses define a first V-shaped sidewall profile, and wherein the substantially V-shaped inner spacer defines a complementary second V-shaped sidewall profile in contact with the first V-shaped sidewall profile.

7. The method of claim 1, wherein a first width of a middle portion of the substantially V-shaped inner spacer is greater than a second width of top/bottom portions of the substantially V-shaped inner spacer.

8. The method of claim 7, wherein a first width is greater than the second width by about 1-5 nm.

9. The method of claim 1, further comprising:
after forming the substantially V-shaped inner spacer, epitaxially growing source/drain features in source/drain regions of the semiconductor device.

10. The method of claim 9, further comprising:
after epitaxially growing the source/drain features, removing the etched-back dielectric layer to form a second gap between adjacent semiconductor channel layers of the plurality of semiconductor channel layers.

11. The method of claim 10, further comprising:
after removing the etched-back dielectric layer, forming a metal gate structure within the second gap between the adjacent semiconductor channel layers and abutting a first V-shaped sidewall profile of the substantially V-shaped inner spacer such that the metal gate structure defines a complementary second V-shaped sidewall profile in contact with the first V-shaped sidewall profile.

12. A method, comprising:
providing a fin structure including epitaxial layers of a first composition interposed by epitaxial layers of a second composition;
forming a dummy gate over the fin structure and a spacer layer on sidewalls of the dummy gate;
replacing the epitaxial layers of the second composition with a conformally deposited dielectric layer;
etching back opposing lateral ends of the conformally deposited dielectric layer to form recesses disposed beneath the spacer layer and between adjacent epitaxial layers of the first composition; and
forming inner spacers within each of the recesses on the opposing lateral ends of the conformally deposited dielectric layer, wherein the inner spacers on the opposing lateral ends each include a first V-shaped sidewall profile.

13. The method of claim 12, wherein the conformally deposited dielectric layer includes an oxide layer or a nitride layer.

14. The method of claim 12, wherein the etching back the opposing lateral ends of the conformally deposited dielectric layer includes using a phosphoric acid (H₃PO₄) chemical etch to form the recesses, wherein the recesses each include a second V-shaped sidewall profile in contact with the first V-shaped sidewall profile.

15. The method of claim 12, wherein a first width of a middle portion of the inner spacers is greater than a second width of top/bottom portions of the inner spacers.

16. The method of claim 12, further comprising:
after forming the inner spacers, removing the etched-back conformally deposited dielectric layer to form a gap between adjacent epitaxial layers of the first composition.

17. The method of claim 16, further comprising:
after removing the etched-back conformally deposited dielectric layer, forming a metal gate structure within the gap between the adjacent epitaxial layers of the first composition and abutting the first V-shaped sidewall profile of the inner spacers such that the metal gate structure defines a complementary second V-shaped sidewall profile in contact with the first V-shaped sidewall profile.

18. A semiconductor device, comprising:
a fin extending from a substrate, wherein the fin includes a plurality of semiconductor channel layers;
inner spacers disposed between adjacent semiconductor channel layers of the plurality of semiconductor channel layers and on either side of a channel region, wherein the inner spacers include a first lateral end having a first V-shaped sidewall profile facing the channel region; and
a source/drain feature disposed within a source/drain region and in contact with a second lateral end of the inner spacers opposite the first lateral end and with end portions of the plurality of semiconductor channel layers.

19. The semiconductor device of claim 18, wherein a first width of a middle portion of the inner spacers is greater than a second width of top/bottom portions of the inner spacers.

20. The semiconductor device of claim 18, further comprising a portion of a metal gate structure disposed between the adjacent semiconductor channel layers, wherein the inner spacers are disposed on either side of the portion of the metal gate structure, and wherein lateral ends of the portion of the metal gate structure have a second V-shaped sidewall profile in contact with the first V-shaped sidewall profile.
